(19) United States
(12) Patent Application Publication
(10) Pub. No.: US 2008/0012151 A1
(43) Pub. Date: Jan. 17, 2008

(54) Method and an Apparatus for Manufacturing an Electronic Thin-Film Component and an Electronic Thin-Film Component

(75) Inventors: Antti Kemppainen, Oulu (FI); Terho Kololuoma, Oulu (FI); Markus Tuomikoski, Oulu (FI); Raimo Korhonen, Tampere (FI); Pasi Laakkonen, Joensuu (FI); Pekka Koivukunnas, Jarvenpaa (FI)

Correspondence Address: VENABLE LLP, P.O. BOX 34385, WASHINGTON, DC, 20043-9998, US

(73) Assignee: AVANTONE OY, Tampere (FI)

(21) Appl. No.: 10/561,225

(22) PCT Filed: Jun. 18, 2004
(86) PCT No.: PCT/FI04/50098

§ 371 Date: Mar. 19, 2007

(30) Foreign Application Priority Data
Jun. 19, 2003 (FI) 20030919

(51) Int. Cl. H01L 23/52; B05C 11/00; H05K 3/04

(52) U.S. Cl. 257/786; 118/44; 29/846; 257/E23.141

(57) ABSTRACT

A method for manufacturing an electronic thin-film component, an apparatus implementing the method, and an electronic thin-film component manufactured according to the method. A lowermost, galvanically uniform conductive layer of electrically conductive material is first formed on a substantially dielectric substrate, from which lowermost conductive layer conductive areas are galvanically separated from each other to form an electrode pattern. On top of the electrode pattern it is then possible to form one or several upper passive or active layers required in the thin-film component. The separation of the lowermost conductive layer into an electrode pattern takes place by exerting on the lowermost conductive layer a machining operation based on die-cut embossing, i.e. embossing, wherein the relief of the machining member used in the machining operation causes a permanent deformation on the substrate and at the same time embosses areas from the conductive layer into conductive areas galvanically separated from each other. The method and apparatus are suitable for manufacturing thin-film components in a roll-to-roll process.

### FIELD OF THE INVENTION

The invention relates to a method for manufacturing an electronic thin-film component according to the preamble of the appended independent claim 1. The invention also relates to an apparatus implementing the method according to the preamble of the appended claim 15. Furthermore, the invention relates to an electronic thin-film component according to the appended independent claim 24.

### BACKGROUND OF THE INVENTION

The use of printed circuit boards as interconnecting boards for various electric components is well known from prior art. Individual components, such as semiconductors, resistors or capacitors are mounted on the circuit board typically by soldering, wherein said components together with the uni- or multiplanar conductive pattern of the circuit board typically form an electrically operating entity, said components forming an electrically operating entity together with the uni- or multiplanar conductive pattern of the printed circuit board.

There are several known ways to manufacture conductive patterns of printed circuit boards. One generally used way is etching, in which areas other than those protected by a so-called resist are removed from a metal layer formed on top of an insulating substrate material by etching. Typically, a photosensitive material is used as a resist, wherein the resist is patterned by photolitography before etching in a manner corresponding to the conductive patterns.

The conductive patterns may be produced also on an. insulating substrate material by means of various electrolytic coating methods (electroplating) or by printing the conductive material in a suitable, for example paste-like form on the desired locations on the surface of the substrate material.

U.S. Pat. No. 4,356,627 discloses a method for producing a conductive pattern that is also based on stamping. According to the teachings of said publication, the metal layer (Cu) laminated on top of an insulating layer (ABS, acetate, polyphenylene sulfone, polyether sulfone, polysulfone) is formed by using a stamping die in such a manner that by a stable deformation produced on the insulating layer, conductive patterns are separated from the metal layer into two different levels, said conductive patterns being electrically separated from each other. Electrical components may further be mounted to these conductive patterns soldering in a conventional way by soldering.

The aim to implement even smaller structural details in electronic devices requires also reducing the dimensions of the conductive patterns on circuit boards functioning as coupling substrates. This, in turn, complicates the mounting of electric components on circuit boards, because the positioning of the components and the soldering technique required for the electrical contacts become more challenging. Furthermore, especially the rapid development of computer and telecommunications technology has evoked an ever increasing need to develop cheaper solutions for the production of various electronic devices, especially pixel displays.

The development of the manufacturing technology of electronic devices has resulted in solutions, in which electrode structures of smaller scale and with larger amount of details are formed on a suitable substrate material instead of using separate printed circuit boards, on top of which electrode structures the required electrically active and other layers are formed directly, wherein said electrode structures remain as parts of these components, and it is possible to eliminate steps related to the mounting of the components on a coupling substrate or the like separately. The active and other layers of the components implemented in connection with the electrode patterns may be formed for example by means of various deposition, coating or printing techniques. Thus, it can be considered that these solutions typically based on thin films are in a way between conventional printed circuit boards and integrated circuits having a very high degree of integration. The materials used in these solutions also typically deviate to some extent from silicon-based semiconductors used in conventional integrated circuits. At present, the focus of interest especially on organic electroluminescent materials (polymers), which have interesting uses especially in optical components.

The line widths of conductive patterns used in circuit boards are typically in the order of>100 μm, even up to several millimeters. The line widths used in integrated circuits, in turn, are typically in the order of 100 nm at present. The present invention relates to electrode patterns utilizing line widths which primarily fall between the aforementioned values, typically in the range of 1 to 50 μm.

Patent publication US 2002/0094594 discloses a solution for manufacturing organic light-emitting structures, so-called OLEDs (Organic Light Emitting Diodes). In principle, OLED structures comprise one or several layers of active material formed between two opposite electrode layers, an anode an a cathode. In addition to these, this structure based on superimposed films or layers may contain separate insulating layers or the like, when required.

According to said US publication an insulating substrate (of glass or plastic) is coated with an organic layer, on top of which organic layer an upper conductive electrode layer (of metal or indium tin oxide, ITO) is formed. This upper electrode layer is patterned according to said publication by means of die-cutting, in which the die-cutter used as a machining member is preferably coated in such a manner that when it is lifted up from the upper electrode layer, it at the same time removes a portion of the conductive material of the electrode layer. According to the publication, it is, when required, possible to implement a patterned lower electrode layer underneath said organic layer, directly on top of the insulating substrate by means of other techniques of prior art (see page 2 of the publication, first paragraph, reference numeral [0030]).

Thus, the publication 2002/0094594 teaches an act of forming an electrode pattern by means of die-cutting on an upper electrode layer produced on top of an organic layer, from which it is relatively easy to remove conductive material by means of a die-cutter, thanks to the relatively low adhesion between the upper electrode layer and the organic layer. On the other hand, when the upper electrode layer is patterned mechanically in this way, one should be careful not to damage the sensitive lower organic layer. However, it can be considered that even when used in this way, the patterning based on mechanical die-cutting has certain advantages for example when compared to chemical methods, because chemical methods may damage the sensitive lower organic layers. In certain applications the method based on die-cutting is also a fast and thus an advantageous way of implementing the patterning of the upper electrode.

However, in many cases it is possible to show that in mass production of electronic devices, particularly the production of the first electrode pattern formed on top of the insulating substrate has a crucial role in view of manufacturing costs and efficiency. This lowermost electrode pattern largely determines the nature of the components that can be implemented thereon for example by growing organic material layers. If it is possible to implement the patterning of the first electrode layer with good accuracy and for instance with sufficiently small line widths, this reduces the requirements set for the active layers formed on top of said electrode layer and for other upper electrode layers, and allows more degrees of freedom in the selection of the manufacturing processes of these layers.

### BRIEF DESCRIPTION AND MOST SIGNIFICANT ADVANTAGES OF THE INVENTION

The main purpose of the present invention is thus to pay more attention than before to, and to offer new solutions for, the patterning of the so-called lowermost electrode layer implemented directly on top of the insulating substrate before the active layers, in thin-film components and other electrical components implemented in a layered manner on the surface of an insulating substrate.

To attain these purposes, the method according to the invention for manufacturing a thin-film component is primarily characterized in what is presented in the characterizing part of the appended independent claim 1. The apparatus according to the invention, in turn, is primarily characterized in what will be presented in the characterizing part of the appended independent claim 15. The thin-film component according to the invention is primarily characterized in what will be presented in the characterizing part of the appended independent claim 24. The other, dependent claims will present some advantageous embodiments of the invention.

It can be said that the central idea of the invention is that an electrode pattern is formed on the lowermost conductive layer arranged on the surface of an insulating substrate functioning as a substrate material by means of a machining operation based on die-cutting, i.e. so-called die-cut embossing, in which the relief of the machining member embosses areas from the conductive layer into electrode areas galvanically separated from each other. In the embossing according to the invention the aim is not to remove material from the lowermost conductive layer, but the electrode areas are galvanically separated from each other by producing a permanent deformation in the substrate by performing the embossing in process conditions suitable for this purpose, and by means of a machining member suitable for this purpose. These process conditions, such as the temperature of the substrate vary to a certain extent depending on the substrate and conducting materials, and the dimensions of the patterns produced thereon by embossing.

In one embodiment of the invention, the lowermost conductive layer arranged on the substrate is machined by embossing in such a manner that electrode areas are formed on several different levels, which levels have different positions in a direction perpendicular to the plane of the substrate (thickness of the substrate), i.e. in a vertical direction. By utilizing, in this way, said vertical distance in addition to the distance in the direction of the plane of the substrate, i.e. the horizontal distance, it is possible to increase the density of the electrode pattern considerably, which is a significant advantage in certain applications. the manufacturing of OFET-transistors (Organic Field Effect Transistor) having a very short channel length or the manufacturing of pixel displays are examples of such applications. Also in components other than those mentioned above, it is possible to attain considerable advantages by means of the invention by defining the vertical dimension of the upper passive or active layers formed on top of the lowermost conductive layer of the component by means of an embossing action exerted on said lowermost conductive layer.

According to a preferred embodiment of the invention, the insulating substrate material is coated with the lowermost conductive layer in a vacuum or low pressure process, and in addition to this at least the electrode pattern of the lowermost conductive layer is implemented by means of embossing in connection with the same vacuum process and preferably substantially in the same process conditions. Preferably, said coating and embossing stages are conducted in a roll-to-roll process, which enables a manufacturing process that is considerably faster, simpler and better suited for mass production than solutions of prior art. In connection with the same process, and preferably again as a roll-to-roll process, it is also possible to implement the formation of other passive or the actual active layers of the product, as well as formation of other upper electrode layers. The formation of said layers may be implemented in a manner best suitable for each application in question, as will be described in more detail hereinafter. It is also possible that one or several upper passive or active layers of the component are formed simultaneously by means of an embossing action directed to the lowermost conductive layer. One example of this is the simultaneous embossing of the lowermost conductive layer and the insulating layer formed thereon.

By means of the invention, it is thus possible to implement for example only the coating of the substrate with a conductive electrode layer or the patterning of said layer by embossing substantially in one single vacuum or low pressure process. Thereafter the product located for example on a roll may be transferred to the subsequent processes, and, if required, to different conditions for the implementation of the required layers. On the other hand, by means of the invention, it is in certain embodiments possible to implement all electrode layers, active layers and protective layers required by the operating electronic device substantially in one and the same process. It is obvious that the larger number of layers it is possible to implement in connection with the same process, the smaller number of additional steps (transfer, cleaning, pre-processing, alignment) are required, and at the same time the risk of contaminating the process is reduced.

To understand the broader significance of the present invention, it is essential to notice the aspect that, according to the understanding of the applicant, the invention for the first time makes it possible in the same process (typically vacuum process) to first grow a conductive layer on a substrate, which layer is necessary for the electrode structure and which layer is then immediately patterned by means of embossing in connection with the same process. The methods of prior art for forming patterned electrode structures, such as photolithography, wet etching and dry etching processes following the same, or different solutions based on anti-stick lubricants or on printable conductor materials are problematic, because the substances used therein typically cause contamination in the processes, wherein it is, in practice, not possible to combine the processing of several (preceding or succeeding) layers in the same process.

Another significant advantage attained by means of the invention is that the line widths of the electrode structures attained by means of embossing according to the invention are narrower than those attained in growing/patterning by means of prior art shadow mask technique. At the same time the processing time required in patterning is also considerably shorter. By means of the well-known prior art photolithography patterning, it is possible to attain sufficient resolution as such, but it involves the drawback that the complexity of the process (separate exposure and etching) cause extensive costs. Furthermore, the electrode pattern produced according to the invention by means of embossing is also well suited for roll-to-roll type continuous manufacturing processes, for which for example the shadow mask technique that requires repeated alignments and cleaning actions is poorly suited. By means of known techniques it is also difficult or even completely impossible to combine several process steps, such as growing and patterning of the conductive layer, to be implemented in the same process.

In connection with the method according to the invention, it is possible to use for example plastics, such as polyester (PET), polyimide (PI), polystyrene (PS) or polycarbonate (PC) as substrate materials. Also other insulating substrate materials may be used, to which materials it is possible to produce a permanent deformation by embossing in suitable conditions. Thus, the substrate material may be for example a laminate formed of plastic or glass, in which the glass layer preferably functions as a background layer on top of which the plastic layer suitable for embossing is laminated. The substrate material may also be paper, paperboard or a corresponding material, on top of which the conductive layer required in electrode structures may be formed for example as a thin metal film.

As a conductive material required for the electrode structures, it is possible to use for example transparent semiconductor oxides (for example ITO), metals (for example Al, Au, Ag or Cu) or conducting polymers (for example PEDOT:PSS, poly(3,4-ethylenedioxythiophene):poly(styrenesulfonate). In certain applications, the conductor material may also be metal or carbon particle ink. The continuous conductive layer composed of these materials may be formed by means of any known method of prior art before the patterning of the conductive layer by embossing according to the present invention.

The components manufactured by means of the method according to the invention may include for example OLED components, OFET components or photocell components. The invention is especially suitable for the manufacture of various light sources based on luminescence or for the manufacture of passive or active display structures.

The advantages provided by the invention relating to the speed and simple structure of the manufacturing process become apparent best when components having a large surface area, such as photocells are manufactured. The invention also enables the simultaneous manufacturing of electrode structures having a narrow line width, on a large surface area, which, in practice, has not been possible by means of prior art methods so far. As a result, the invention makes it possible to attain significant savings in costs and increases in manufacturing efficiency in various different applications.

The implementation of line widths narrow enough and electrode structures of good quality by embossing requires suitable process conditions and especially also suitable properties of the machining member, such as a pressing block or plate used in the embossing.

Because a certain permanent deformation is implemented in the substrate material in the embossing process according to the invention, the embossing of for example plastics takes preferably place at temperatures that are close to the so-called glass transition temperature of plastic (depending on the material approximately 70° C.). At said temperature, in a so-called glass transition point the properties of plastic change from a glassy state to a more rubbery state. The heating for the embossing purpose is advantageous also for other kinds of substrates than plastic substrates.

As to the pressing plate arranged around the pressing block functioning as a machining member, or in roll-to-roll processes around a reel or the like, an advantageous structure is such in which “side walls” substantially vertical to the plane of the surface are used in the relief to attain the necessary variations in height, and to form sharp edges that cut well the conductive layer. This vertical character of the side walls significantly facilitates the cutting of the contact between the different conductive areas of the conductive layer into separate electrode patterns, and material from the target is not likely to adhere on the surface of the machining member. Furthermore, the aforementioned shape of the relief is advantageous when the aim is to utilize the surface area of the substrate as efficiently as possible and to attain narrow line widths at the same time. When the cutting edges of the relief are sharp enough, the side walls may be slightly inclined without significantly impairing the patterning result in the embossing.

### BRIEF DESCRIPTION OF THE DRAWINGS

The invention and its fundamental properties as well as the advantages to be attained by means of the invention will become more evident for the person skilled in the art from the following description in which the invention will be described in more detail by means of a few selected examples, at the same time referring to the appended drawings, in which

FIG. 1 shows, in principle, a diagram of a roll-to-roll process according to the invention, in which the insulating substrate is vacuum coated with a conductive layer, and the conductive layer is thereafter embossed in connection with the same vacuum process,

FIGS. 2a to 2f show a way of producing a pressing block used in embossing according to the invention,

FIG. 2g shows in principle the copying of a relief into a pressing plate having a large surface area,

FIG. 3 is an example of a SEM image showing the surface profile of a pressing block suitable for embossing according to the invention,

FIG. 4 is an example of a SEM image showing an ITO/PET layer structure embossed by means of a pressing block according to FIG. 3,

FIGS. 5a and 5b show, in principle, side and top views of a pixel display based on OLED components implemented according to prior art,

FIG. 6 shows, in principle, a top-view of an OLED pixel display implemented according to the invention,

FIG. 7 is an example of a SEM image showing a prior art OFET transistor which comprises finger-like and overlapping Source and Drain electrodes,

FIG. 8 shows, in principle, a cross-sectional view of a channel structure of an OFET transistor,

FIG. 9 shows, in principle, a cross-sectional of view an electrode structure separated from a conductive layer on top of an insulating substrate by means of embossing according to the invention,

FIG. 10 shows, in principle, a cross-sectional view of an OFET structure implemented on top of the electrode structure according to FIG. 9,

FIG. 11 shows, in principle, a cross-sectional view of a second OFET structure implemented on top of the electrode structure according to FIG. 9, and

FIG. 12 shows, in principle, a cross-sectional view of a third OFET structure implemented on top of the electrode structure according to FIG. 9.

### MORE DETAILED DESCRIPTION OF THE INVENTION

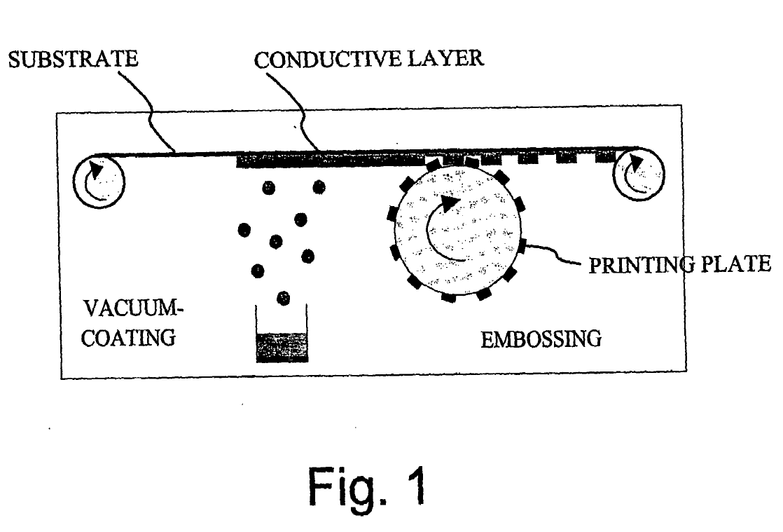

FIG. 1 shows, in principle, a roll-to-roll process, in which a plastic functioning as a substrate is first vacuum coated with a conductive layer, and thereafter an electrode pattern is formed in said conductive layer by embossing in connection with the same vacuum process by means of a pressing plate arranged around a reel or the like. The tests conducted by the applicant have shown that by means of embossing it is possible to manufacture very narrow line structures in the order of 1 to 50 μm in width on a vacuum coated plastic substrate.

FIG. 1 shows, in principle, that both the vacuum coating and the embossing are arranged to take place in the same chamber. This is not, however, the only possible embodiment of the invention, but in view of mass production the central aspect is primarily that it is possible to convey the substrate from one roll to another in one single run without having to move the rolls/substrate into different processing devices every now and then. Thus, it is possible to avoid the need to pump down the pressure of the process repeatedly, which is known to be a time-consuming task. Thus, it is also possible to use several different chambers in the arrangement according to FIG. 1, substantially the same pressure conditions prevailing in all of them.

### Manufacture of a Pressing Block or Plate

The pressing block suitable for embossing is typically a nickel pressing plate/block that may be manufactured for example by lithographical methods which are known from other contexts of prior art. The most important manufacturing techniques of a pressing plate include direct resist lithography or a combination of the resist lithography and dry etching technique.

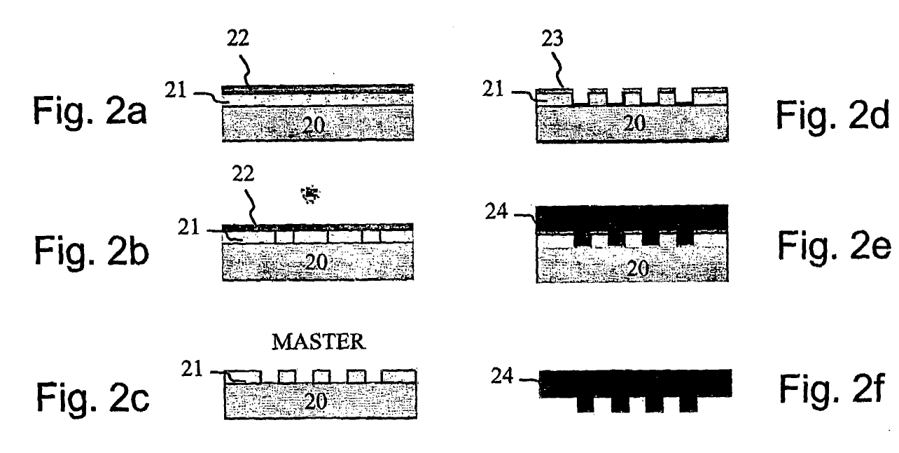

FIGS. 2a to 2f present, in principle, the process stages where the desired relief of the surface structure is formed on the pressing block required for embossing by performing the patterning of the resist layer, in this case by using an electron beam. It should be noticed that the invention is not limited solely to the use of electron beam embossing, but it is possible to use for example a laser beam in the patterning.

FIG. 2a presents, in principle, the coating of a substrate material 20 (glass, quartz, silicon, etc.) with a resist layer 21 and a conductive layer 22 required for electron beam embossing. The purpose of said conductive layer 22 is to transmit away an electric charge produced by the electron beam used in the embossing. FIG. 2c shows the development of the resist layer 21, as a consequence of which a part of the resist layer may be selectively removed, in which case the so-called master element remains. In FIG. 2d, a conductive layer 23 is evaporated onto this master element, on top of which is further grown a nickel pressing block 24 in FIG. 2e. In FIG. 2f, the nickel pressing block is presented as removed from the master element of FIG. 2c.

Furthermore, another alternative method to produce a relief is to utilize a resist structure according to FIG. 2c, on top of which a metal (Cu, Al, or the like) or a dielectric layer (SiO₂) functioning as mask material in the dry etching process is evaporated, wherein a structure according to FIG. 2d is attained. By placing said structure in a solvent dissolving the resist, it is possible to remove the resist patterns, and the remaining metal or dielectric material is left on top of the substrate in the patterned locations. Thereafter the substrate is placed in a separate plasma chamber into a dry etching process, in which the substrate and the mask material are eroded by means of a directed gas plasma in a direction vertical to the plane of the substrate. As a result of this, the patterns produced by the mask material are transferred to the substrate. The pressing block 24 is grown from the patterned substrate by first coating a conductive layer 23 on top of the structure and by electrolytically growing the pressing block thereon. In addition to the methods above, there are several other alternative lithography methods known as such and their different combinations for the formation of patterns on a nickel pressing block.

In view of the present invention, an essential aspect in producing a master element necessary in the manufacture of the pressing block is that the method is capable of replicating certain properties of the pressing block, of which the most important ones include the vertical orientation of the walls of the relief, and the quality of the edges of the relief. Thus, the manufacturing method should be selected so that it is optimal for each separate pattern geometry. Direct laser lithography may be used for line widths of>1.5 μm and line widths smaller than this are typically produced by means of an electron beam. Another essential aspect in view of the invention is the depth of the lines in the relief. It is known that for example the line width of 25 μm and depth 50 μm can be produced with a nearly vertical wall by optimizing the exposure and development process of the resists accurately. However, in most cases it is easier to use the above-described dry etching process by means of which it is possible to produce nearly completely vertical walls.

The nickel pressing block 24 of FIG. 2f can be used for embossing as such, or additional pressing blocks may be grown from it by repeating the process step according to FIG. 2e.

By using the above-mentioned lithographic methods, it is possible to produce pattern areas, whose surface areas are with modern production techniques<8″×8″. Larger areas are produced with a recombining method shown in principle in FIG. 2g, where the individual pressing block 24 produced with the above-presented methods is copied with hot embossing or molding methods on a larger substrate by copying the structure onto the surface of the substrate in the xy directions defined by its plane.

In copying by hot embossing, the nickel pressing block 24 produced in the afore-mentioned way is positioned onto a metal supporting plate of the size of the pressing block in question, and with it, the pattern is pressed on an appropriate plastic material, for example on PMMA material (polymethyl-methacrylate), with the hot embossing process. By repeating the process several times and at different places of the plastic material, a new master element comprising a larger surface area may thus be produced, from which a pressing block/pressing plate comprising a larger area is electrolytically grown.

It is also possible to perform the combining process by spreading liquid polymer material onto a plastic, glass or quartz substrate comprising a larger surface area, to which material the pattern of the nickel pressing block 24 is pressed. By hardening the polymer locally (for example by heating, with UV light or by using an adequate hardening time), the pattern structure may be produced in said place on top of the substrate. By repeating the process at several different points, a master element having a larger surface area may again be formed, and a pressing plate suitable to be placed around a roll or the like may further be grown from the same.

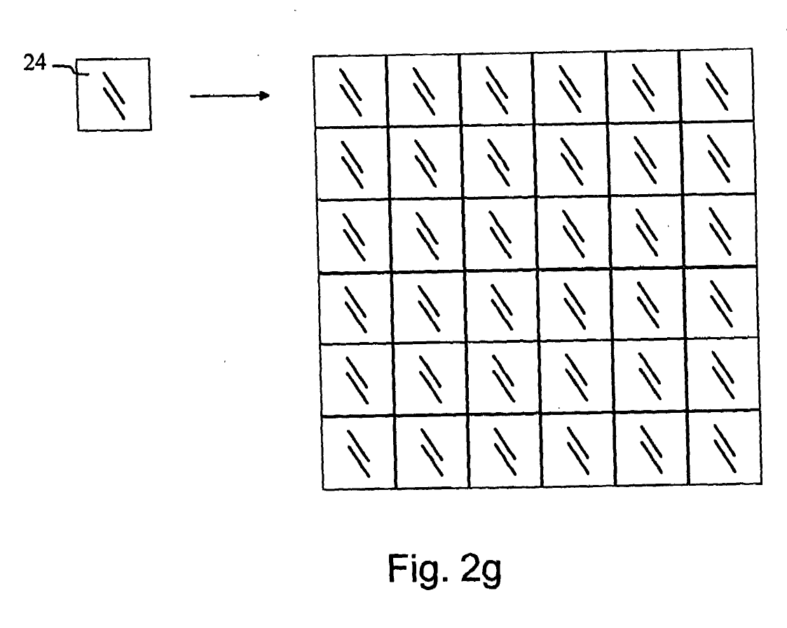

FIG. 3 shows a scanning electron microscopy (SEM) image of the surface profile of a pressing plate suitable for embossing according to the invention. The area in the middle of FIG. 3 is on a 25 μm higher level than the area on the edges. It can be seen that the relief of the pressing block thus has substantially vertical walls and sharp cutting edges. The depth of the profile when embossing for example an ITO/PET structure is preferably in the order of 1 to 25 μm and the line width is in the order of 1 μm at its narrowest. The selection of the depth of the profile as well as the narrowest possible line width vary depending on the conductive layer to be embossed and the material of the substrate underneath the same.

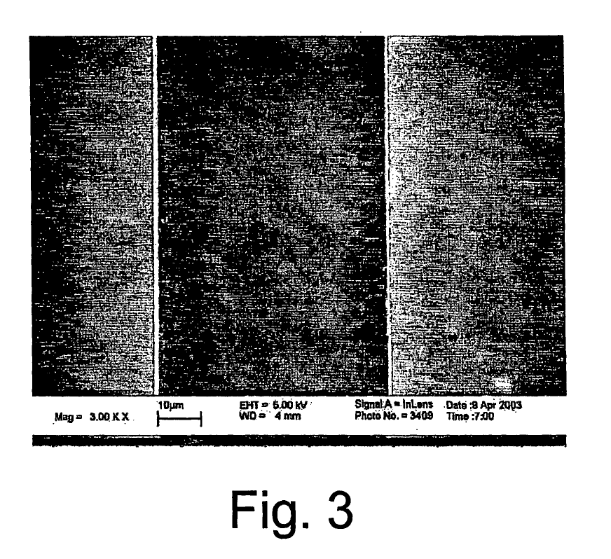

FIG. 4 shows a SEM image of an ITO/PET layer structure embossed by means of a pressing plate according to FIG. 3 at a temperature of 20° C. FIG. 4 shows that the structures have been pressed into two different levels. The area in the middle of the figure is on a 15 μm lower level than the dark areas on the edges, wherein said pressing has cut the ITO conductive layer of 100 nm in thickness on top of the PET plastic substrate. It can be seen that, when compared to the structure of the pressing plate according to FIG. 3, the dimensions of the pattern formed in the conductive layer are equal in width and the cutting edge is even. The roughness of the cutting edge is below 2 μm.

In the embossing according to the invention, it is preferably possible to use PET as the substrate material, but other possible materials are PI, PS and PC. Of these materials at least PET can be readily obtained on a roll, wherein it is easy to use it in a roll-to-roll process.

For example in OLED components or other optical components, it is possible to use transparent semiconductor oxides, typically ITO as the material of the lowermost electrode structure (anode) formed on top of the substrate. The resistance value of ITO is typically few tens of ohms per square in film thicknesses of several tens of hundreds of nanometers, and in the area of visible light its transmission is typically>75%. It is possible to coat the PET film with an ITO film by means of vacuum growing methods known as such, and between the PET and ITO layers it is possible to use for example a thin silicon dioxide layer (SiO₂), which functions as an adhesive layer between said layers. It is also possible to use other protective layers between the aforementioned layers.

Even though the invention is primarily intended for patterning by means of embossing of the lowermost electrode layer formed on top of a substrate, it is naturally possible to implement embossing also in the patterning of the other upper electrode layers for example in the way disclosed in the patent publication US 2002/0094594. When the upper conductive layers of a multilayer structure are patterned by means of embossing, it is possible to use a suitable protective layer underneath the layer to be patterned, the deformation according to the invention being produced in said protective layer, thus enabling the breaking of contacts for the part of the layer to be patterned.

In an embodiment of the invention it is possible to coat the plastic substrate in connection with the same roll-to-roll process first by sputtering in a vacuum a substantially uniform ITO layer having a thickness of for example 100 nm. Thereafter said ITO layer is patterned by means of embossing according to the invention to form an anode electrode. One or more layers of organic material are formed on top of the anode electrode by means of thermal vacuum evaporation. The thickness of these layers may be for example 50 to 200 nm. Further, a metal (for example Mg, Ag or Al) cathode electrode is formed on top of the organic layers. The cathode electrode may be patterned either by means of embossing or by another prior art method. When the lines of the cathode electrode are formed in perpendicular to the lines of the anode electrode, it is possible to control the pixels formed in the crossing of said lines, one at a time, thus forming for example an OLED pixel display. In the final processing of the component, the structure is protected with the necessary protective layers etc., and, if required, it is cut and wired to form finished components.

As to the conductive layers to be patterned, priority is given in this invention to semiconductor oxides, such as ITO. Said materials form a glass-like layer on the substrate, which may be cut by means of embossing according to the invention, said cutting being based on the permanent deformation produced in the substrate material underneath. However, the invention is not restricted solely to electrode layers made of semiconductor oxides, but it is also possible to use metals (such as Al, Au, Ag, Cu) or polymer (such as PEDOT, PSS) as electrode materials in such embodiments where an optical transparency of the electrode layer is not required.

The line widths required in the electrode patterns are in each case determined according to the embodiment to be manufactured. By means of the embossing according to the invention it is for example in the ITO layer possible to attain line widths in the order of 1 μm.

When the substrate material is plastic, the embossing takes place in temperatures that slightly exceed the glass transition temperature of plastic, in which temperature, at the so-called glass transition point, the properties of plastic are changed from a glassy state to a rubbery state. However, in these temperatures the ITO layer on top of the plastic substrate is not softened, which is a prerequisite for reliable cutting of said layer along accurately defined lines by embossing. Suitable temperature of the substrate in which the substrate is in such a state in which a permanent deformation is attained by embossing, may be arranged either by pre-heating the substrate before embossing and/or using a heated pressing block or plate for the embossing. It is an advantage of the heated machining member that thus the heating is temporarily directed only to the part of the substrate to be machined, and it is not necessary to heat the entire substrate material.

As was mentioned above, the pressing block or plate is preferably manufactured to have a nickel surface. It is a challenging task to produce a relief with as straight walls and sharp cuffing edges as possible, but it may be attained for example by means of the above-described technique based on electron beam patterning and dry etching. It is also advantageous to manufacture the pressing block for example in silicon by etching the material in the direction of the crystal.

In the following, the invention will be described in more detail by using the manufacture of OLEDs and OFETs as specific examples. These examples clearly show for anyone skilled in the art, among other things, how it is possible to efficiently utilize the vertical direction of the substrate and the conductive layer in the embossing.

### Manufacture of a Pixel Display Based on OLED Components

The use of OLED components in various display embodiments is in the focus of interest at present, because they offer the possibility to manufacture display components at lower costs when compared to conventional pixel displays. According to the understanding of the applicant, the present invention makes it possible to manufacture pixel displays in a simpler manner and even with lower costs when compared to prior art methods. Furthermore, by means of the invention it is possible to implement a better pixel resolution in displays by utilizing the vertical distance of the adjacent electrodes in addition to the horizontal distance more efficiently than in prior art.

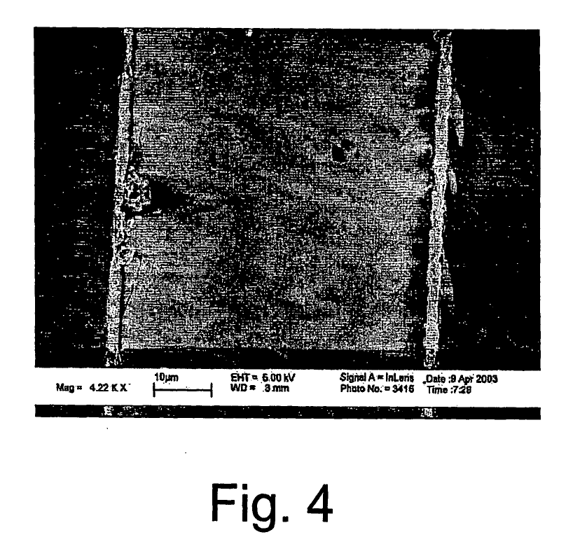

FIGS. 5a and 5b show in principle a pixel display based on OLED components as it is manufactured according to prior art. The pixels of the display are formed in the intersection between crossing stripe-like electrodes (typically lower anode and upper cathode). Generally, it can be considered that both crossing electrodes of the OLED pixel must be patterned to have a width less than 100 μm, so that a display with sufficiently high resolution can be attained. By means of a prior art shadow mask it is in practice possible to attain an electrode width of approximately 200 to 300 μm. If a so-called RGB full colour display is produced, the total length of the so-called virtual colour pixel formed together by three adjacent basic colour pixels (red, green and blue) thus approaches 1 mm, which is too large to be suitable for high resolution displays. Furthermore, the drawbacks of the shadow masks include repetitive alignments and cleanings. By means of a prior art photolithography patterning it is possible to reach a resolution of under 1 μm, but it has the drawback that manufacturing costs are high and it is poorly suited for roll-to-roll processes. Furthermore, the etching chemicals used in photolithography cause problems or prevent the combination of different process steps into a single entity.

Thus, high resolution displays are typically implemented on a silicon substrate, on which it is possible to manufacture pixels of sufficiently small size by means of prior art techniques. However, it is difficult to lower the manufacturing costs of the silicon substrate displays to such a level which, in principle, may be attained by using organic materials in mass production.

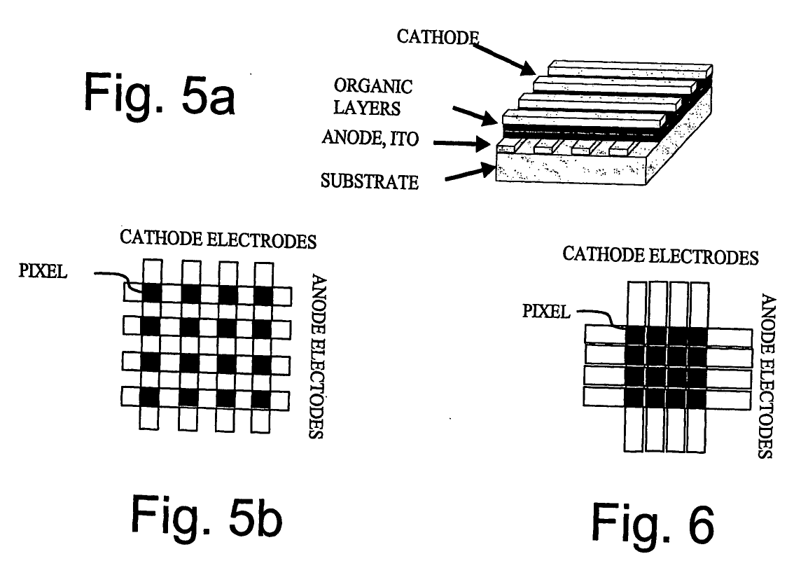

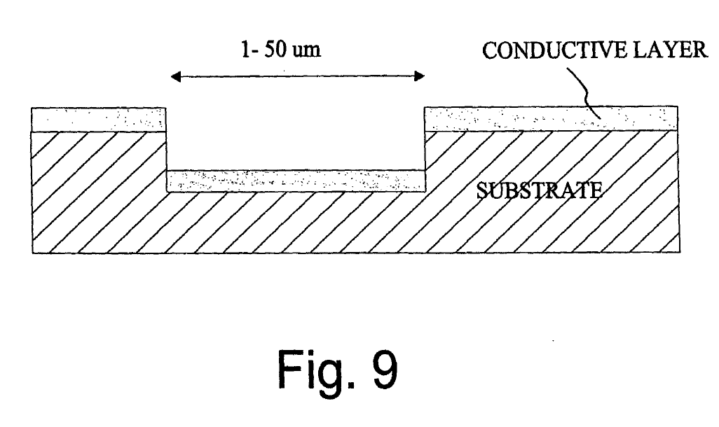

FIG. 6 shows an OLED pixel display implemented according to the invention. By utilizing the electrodes formed on different levels in the direction perpendicular to the plane of the substrate, i.e. in the vertical direction, by means of embossing, it is possible to increase the density of the electrode pattern significantly, which also enables a better pixel resolution than before. The advantage of electrode patterns embossed on two different levels becomes more apparent also in FIGS. 9 to 11 hereinafter. When the line width of the electrode pattern is for example in the order of 50 μm, sufficient resolution is attained in the majority of embodiments, including colour displays.

Thus, the present invention makes it possible to manufacture OLED pixels in such a manner that the pixel size is sufficiently small also for high resolution displays. Another significant advantage of the invention is that it also enables the manufacture of OLED pixels in a roll-to-roll process, which considerably reduces the manufacturing costs of pixel displays in mass production.

### Manufacture of OFET Components

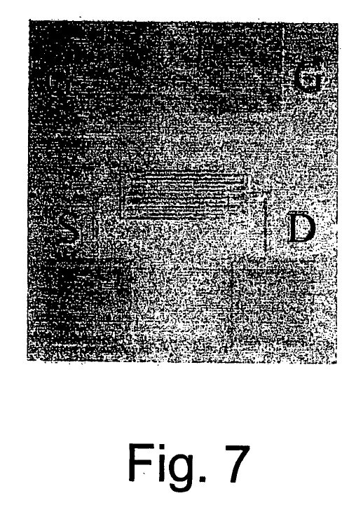

It is known as such that in organic field effect transistors based on thin films, one central requirement to be set for the manufacturing technique is the capability to manufacture sufficiently small channel lengths between electrodes, which have a finger-like structure and are arranged overlappingly with respect to each other. FIG. 7 is a SEM example image showing the structure of an OFET transistor, in which the overlapping finger-like Source and Drain electrodes S, D can be seen. In this context the channel of the field effect transistor is the area between the two adjacent fingers of these opposite electrodes, which has a certain length (distance between electrode fingers between opposite electrodes S, D) and width (distance within which the opposite electrodes S, D overlap). In view of the operation of the transistor, the ratio between the length and the width of the channel is an essential parameter.

The current IDS between the OFET transistor and the Drain-Source electrodes can be estimated according to the formula (1)

$$\begin{matrix}{I}_{DS} = \frac{{WC}_{i}}{2 L} {μ ( {V}_{GS} - {V}_{t} )}^{2} & ( 1 ) \\ {C}_{i} = \frac{{ɛ}_{0} {ɛ}_{r}}{{d}_{ax}} & ( 2 )\end{matrix}$$

in which μ=mobility of the charge carrier in the channel material
V_{GS}=Gate-Source voltage
Cᵢ=specific capacitance of the insulating layer
W=channel width
L=channel length
Vₜ=threshold voltage of the transistor
dₒₓ=thickness of the insulating layer
εᵣ=permittivity of the insulating material
ε₀=permittivity in vacuum

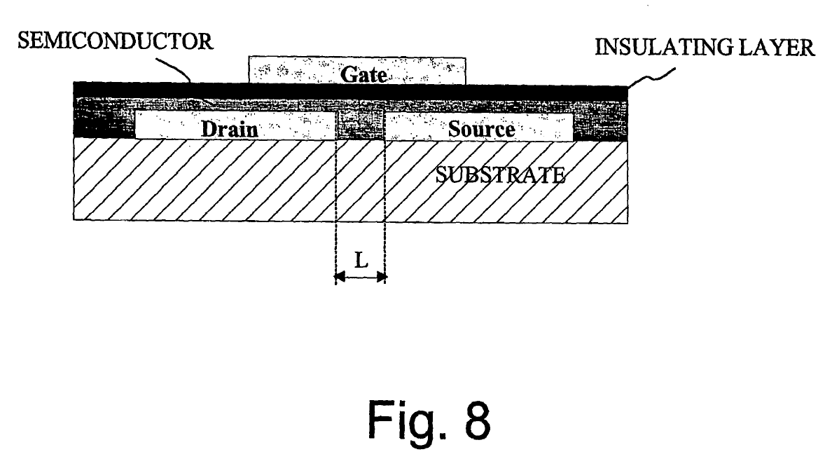

FIG. 8 shows, in principle, a cross-sectional view of the channel structure of an OFET transistor.

Typically the mobility of the charge carriers of organic channel materials vary between 10⁻³ and 0.1 cm²/Vs, while for silicon in crystal form it is considerably higher, in the order of 10³ cm²/Vs. This restricts the current obtained from an organic transistor considerably in accordance with formula (1). On the other hand, the current is substantially dependent on the ratio of the width W and the length L of the transistor channel. The aim is to maximize this ratio W/L by producing for example electrodes patterned in a finger structure according to FIG. 6. Furthermore, the size of the transistor affects the threshold voltage Vₜ of the transistor in such a manner that the reduction of the size reduces the required threshold voltage. In many embodiments low threshold voltage levels are an essential requirement set for the transistor.

It is a direct result of the foregoing aspects that the patterning of the Drain and Source electrodes must be implemented very accurately. Furthermore, the quality of the patterning must be good, because even occasional shortcuts between the electrodes typically spoil the performance of the transistor.

Known prior art methods based on photolithography and etching do, in fact, enable accurate electrode patterning, but they are slow and expensive processes which require a number of different process steps. Thus, they are poorly suited for mass production, and in practice they are not suitable for roll-to-roll processes.

There are other prior art methods suitable for the patterning of electrodes, such as the shadow mask technique, but generally it can be said that the methods by means of which it is possible to reach a resolution of sufficiently high quality (in the order of 1 μm) in the length L of the channel are not suitable for mass production, and especially not for roll-to-roll processes.

The solution according to the invention based on embossing, in turn, is suitable for implementing the Drain and Source electrodes necessary in OFET transistors also in mass production and as a roll-to-roll process.

Referring to FIG. 8, a conductive layer on top of an insulating substrate material is first formed, for example of a metal (such as Al, Cu, Ag or Au), ITO, or of a conductive polymer (such as rr-PHT, regioregular poly(3-hexylthiophene)). The Source and Drain electrodes are formed in this conductive layer by embossing according to the invention. It should be noted that the dimensions L, W of the transistor channel are now directly defined by the pattern of this lowermost electrode layer. Thus, the application of the organic semiconductor layer on top of the electrodes, as well as the formation of the subsequent insulating layers and the formation of the Gate electrode are not as critical in view of their pressing accuracy. The organic semiconductor layer, the channel material, may be made for example of pentacene, or of a suitable oligotiophene compound.

An insulating layer is implemented on top of the organic channel material, which insulating layer is typically made of SiO₂, or dielectric polymer, such as polyester, PVP (poly-vinylphenol) or PMMA. The patterning of the insulating layer does not affect the dimensions L, W of the transistor channel any more, whereby the accuracy requirements in the manufacture of the same are less strict. However, the thickness of the insulating layer is an essential factor in view of the function of the transistor, as shown by formula (2). The insulating layer must be as thin as possible, but it must not contain holes or the like that make shortcuts possible. The insulating layer may typically be implemented for example by means of vacuum evaporation, sputtering or pressing.

A Gate electrode of a suitable material, for example metal (such as Al, Cu), conductive graphite or metal particle ink, or conductive polymer, such as polyaniline, is also implemented on top of the insulating layer. This stage is no longer so critical in view of the pressing accuracy, because the dimensions of the transistor channel have been determined already in connection with the electrode pattern of the lowermost conductive layer.

On the basis of the foregoing, it is obvious that the use of embossing according to the invention in the manufacture of OFET components is advantageous because by means of this method it is possible to pattern the lowermost, and in view of the properties of the transistor the most important conductive layer very accurately. After the implementation of the Drain and Source electrode pattern of the lowermost conductive layer, there are considerably more degrees of freedom in the implementation of the subsequent layers, because it is now possible to allow a certain degree of inaccuracy for them without substantially affecting the performance of the transistor.

FIGS. 9 to 11 show in more detail some possibilities for the structures of the OFET transistor made by means of embossing. These figures also show how the invention enables accurate and small channel lengths L by utilizing the vertical direction of the substrate in a new way.

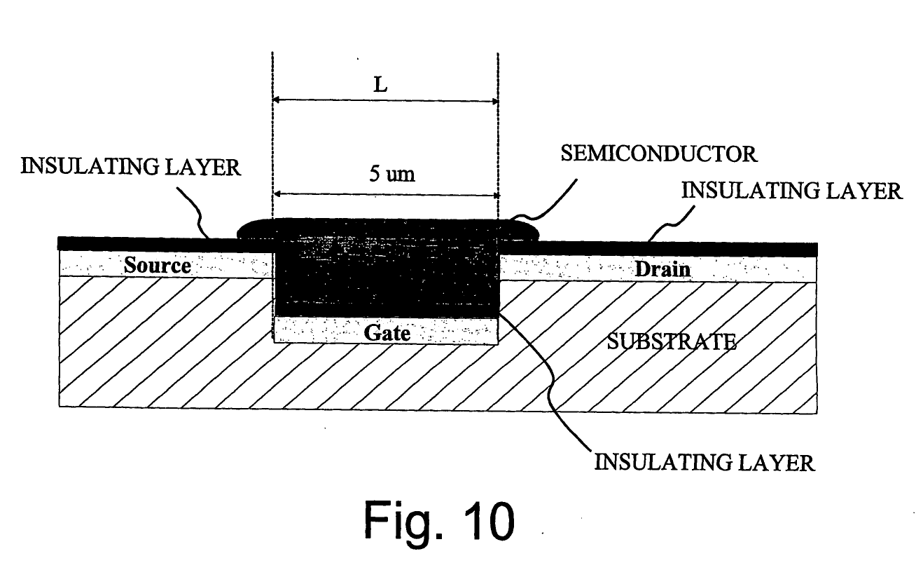

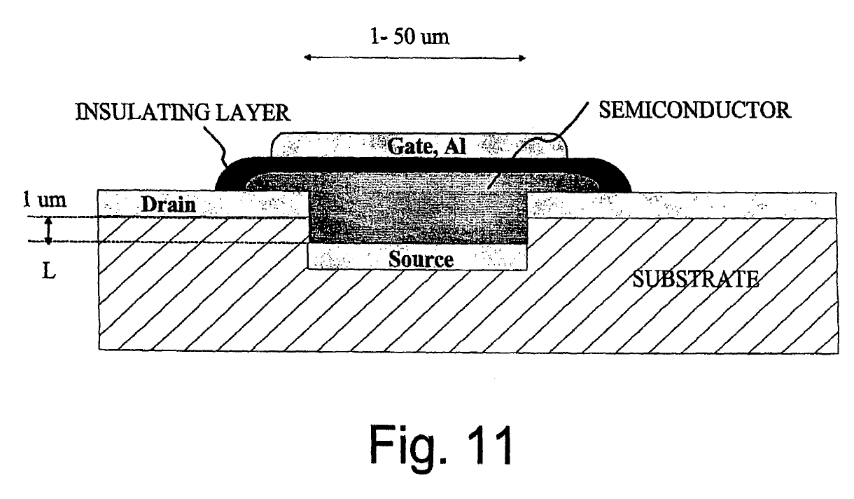

FIG. 9 shows, in principle, a narrow electrode separated from the conductive layer (for example ITO, aluminium, or conductive polymer) on a lower level by embossing according to the invention, the electrode being on top of an insulating substrate, and which electrode may function as a basis for the transistor structures shown in FIGS. 10 and 11. According to the figure, the width of said electrode may be in the order of 1 to 50 μm. It is obvious that depending on the embodiment, it is also possible to utilize only the conductive layer remaining on top of the substrate on the original level, wherein the part of the conductive layer shown in FIG. 9, separated from said level to a lower vertical plane is not at all utilized as an electrode. The situation may also be opposite, wherein only the electrode lower in the vertical direction is taken in use.

FIG. 10 shows in principle a field effect transistor implemented on top of the structure according to FIG. 9, in which the aforementioned electrode separated from the conductive layer operates as a Gate electrode. There is an insulating layer on top of the Gate electrode, and on top of said insulating layer there is further an organic semiconductor layer that fills the recess made by embossing. In this case both the conductive layer and the passive insulating layer on top of the same, produced for example by vacuum growing, may be embossed simultaneously. The contacts for Source and Drain electrodes are made for example of aluminium on top of the electrodes patterned on both sides of the aforementioned recess. The contact point of the Gate electrode may be produced in a similar way next to the transistor structure by wiring a suitable area for the electrode. In the structure of FIG. 10, the distance between the Source and Gate electrodes becomes equal to the length L of the channel, which in this example is in the order of 5 μm.

FIG. 11 shows yet another alternative for the structure of the field effect transistor. In this case the electrode separated from the conductive layer by means of embossing operates as a Source electrode on top of which a vertical recess is embossed, in which recess an organic semiconductor is formed and on top of the same a Gate electrode. The Drain electrode is formed by a conductive layer remaining on the upper vertical level on the surface of the substrate. It is an advantage of the invention that the length L of the transistor channel is now determined according to the vertical embossing depth. Thus, it can be controlled very accurately by means of the relief of the pressing block used in the embossing. This also makes channels lengths of under 1 μm, for example in the order of 500 nm, possible.

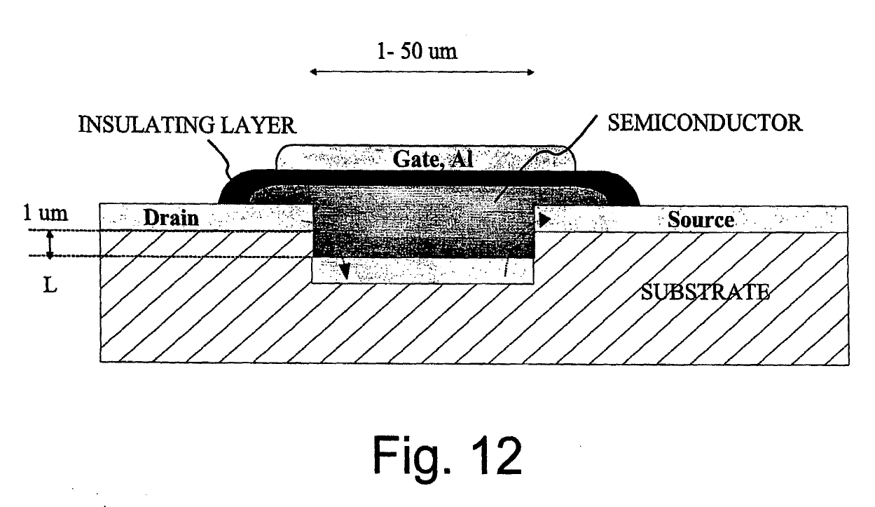

FIG. 12 shows another alternative for the structure of the field effect transistor. In this case, the portion of the conductive layer embossed on the lower vertical level, which in the solution according to FIG. 11 operates as a Source electrode, is not electrically coupled as an electrode at all, but the Drain and Source electrodes are now both arranged on the upper vertical level on different sides of the embossed recess filled by the semiconductor channel material. In the solution of FIG. 12, the effective channel length is a length in the order of 2×1 μm, because the current between the Source and Drain electrodes circulates according to the arrows shown with broken lines in the figure via said electrically floating electrode located on the lower level. It is a special advantage of this structure that slight ruptures or other flaws possibly produced in said floating electrode in connection with the embossing of the conductive layer do not necessarily affect the operation of the transistor.

The example structures shown in principle in FIGS. 10 to 12 make the significant advantages attained by means of the electrode pattern based on embossing of the first conductive layer, according to the invention, clearly apparent for anyone skilled in the art. Accurate electrode pattern of the first conductive layer provides clear process advantages which are significant in view of the mass production of the components. When the electrode pattern of the first conductive layer is implemented with a sufficient accuracy both in the vertical and horizontal directions, it is now possible to combine the implementation of the subsequent layers by means of prior art methods that might be slightly less accurate, but well suited for mass production, without reducing the performance of the components. On the other hand, in connection with the embossing of the lowermost conductive layer it is at the same time possible to form other upper passive (insulating) or active layers.

It is, of course, obvious that the invention is not limited solely to the embodiments presented in the previous examples, but the invention is to be interpreted only according to the limitations set by the appended claims. Thus, the invention is not restricted solely for example to the manufacture of the above-described components, but by means of the invention it is possible to manufacture for example solar cells or photocells. To manufacture active matrix displays it is possible to combine both OFET and OLED structures on the same substrate.

In addition to the above-described process stages it is possible to use other process stages in connection with the invention, when required, for example to implement the insulation and fitting layers between different material layers. Furthermore, it is possible to utilize for example RIE etching (Reactive Ion Etching) or other plasma treatment to clean the embossed conductive layer or the other layers formed simultaneously, or the clean the cutting traces before implementing the subsequent layers.

1-33. (canceled)

34. A method for manufacturing electronic thin-film components, said method comprising:
selecting a substantially dielectric substrate;
forming a lowermost, galvanically uniform conductive layer of an electrically conductive material on said substrate;
galvanically separating conductive areas from each other from said lowermost conductive layer to form an electrode pattern by exerting on the lowermost conductive layer a machining operation based on die-cut embossing, wherein the relief of the machining member used in the machining operation causes a permanent deformation on the substrate and at the same time embosses areas from the conductive layer into conductive areas galvanically separated from each other, said conductive areas being on at least two different levels, which levels have different positions in a direction perpendicular to the plane of the substrate; and
forming one or several upper layers required in the thin-film component on top of said electrode pattern.

35. The method according to claim 34, wherein by means of said embossing operation exerted on the lowermost conductive layer, one or more upper layers of the thin-film component are formed simultaneously.

36. The method according to claim 34, wherein the lowermost conductive layer formed on the substrate, which is to be patterned by means of embossing, is produced by vacuum coating.

37. The method according to claim 36, wherein said vacuum coating and embossing are performed in the same vacuum process.

38. The method according to claim 34, wherein said dielectric substrate is selected from a group consisting of plastic, glass, paper, paperboard, and a laminated combination thereof.

39. The method according to claim 38, wherein the substrate material is heated for the embossing.

40. The method according to claim 39, wherein when the substrate material contains plastic, the embossing of said lowermost conductive layer is performed at a temperature, which is slightly above the glass transition temperature of said plastic material.

41. The method according to claim 34, wherein the material of the lowermost conductive layer is selected from a group consisting of transparent semiconducting oxide, non-transparent semiconducting oxide, metal, conductive ink, conductive polymer, and a combination thereof.

42. The method according to claim 34, wherein the vertical depth of the machining member used in embossing is selected from the range of 1 to 50 μm.

43. The method according to claim 34, wherein the horizontal line widths used in the embossing are selected from the range of 1 to 50 μm.

44. The method according to claim 34, wherein the relief of the machining member used in the embossing is selected so that it has substantially upright walls in the vertical direction.

45. The method according to claim 34, wherein a nickel pressing block or plate is used as the machining member in the embossing, the relief of the master of said plate being formed by means of direct resist lithography.

46. The method according to claim 34, wherein a nickel pressing block or plate is used as the machining member in the embossing, the relief of the master of said plate being formed by a combination of resist lithography and dry etching technique.

47. The method according to claim 34, wherein several process stages are performed in the same roll-to-roll process.

48. The method according to claim 34, wherein the electrode pattern formed by means of embossing or the upper passive or active layers formed simultaneously by means of embossing are post-treated by means of a plasma processing.

49. An apparatus for manufacturing electronic thin-film components on a substantially dielectric substrate, said apparatus comprising:
first growing means for growing a lowermost, galvanically uniform conductive layer of an electrically conductive material on said substrate;
patterning means for galvanically separating the conductive areas from each other from said lowermost conductive layer to form an electrode pattern, said patterning means being embossing means based on die-cut embossing, said means comprising at least one machining member whose relief causes a permanent deformation on the substrate and at the same time embosses areas from the conductive layer into conductive areas galvanically separated from each other, said patterning means being arranged to form said conductive areas by said embossing operation such that said conductive areas are on at least two different levels, which levels have different positions in a direction perpendicular to the plane of the substrate; and
second growing means for forming one or several upper layers required in a thin-film component on top of said electrode pattern.

50. The apparatus according to claim 49, wherein said patterning means are arranged to form one or several upper layers of the thin-film component simultaneously by means of said embossing operation exerted on the lowermost conductive layer.

51. The apparatus according to claim 49, wherein said first growing means for forming the lowermost conductive layer to be patterned by means of embossing on the substrate are vacuum coating means.

52. The apparatus according to claim 51, wherein said vacuum coating means and embossing means are arranged in the same vacuum process.

53. The apparatus according to claim 49, wherein the vertical depth of the relief of the machining member used in embossing is in the range 1 to 50 μm.

54. The apparatus according to claim 49, wherein the relief of the machining member used in the embossing is arranged so that it has substantially upright walls in the direction perpendicular to the plane of the substrate.

55. The method according to claim 49, wherein the machining member used in the embossing is a nickel pressing plate, the relief of the master of said machining member being formed by means of a combination of resist lithography and dry etching technique.

56. The apparatus according to claim 49, wherein at least said first growing means and said patterning means are arranged to be in the same roll-to-roll process.

57. An electronic thin-film component, comprising:
a substantially dielectric substrate;
a lowermost conductive layer of an electrically conductive material formed on said substrate, wherein said conductive layer is patterned into conductive areas galvanically separated from each other and forming an electrode pattern by exerting on the lowermost conductive layer a machining operation based on die-cut embossing, wherein the relief of the machining member used in the machining operation causes a permanent deformation on the substrate and at the same time embosses areas from the conductive layer into conductive areas separated from each other galvanically, said conductive areas being on at least two different levels, which levels have different positions in a direction perpendicular to the plane of the substrate; and
one or several upper passive or active layers formed on top of said electrode pattern.

58. The component according to claim 57, wherein the component comprises one or several upper layers, which are formed by the same embossing operation exerted on the lowermost conductive layer.

59. The component according to claim 57, wherein the material of said substrate is selected from a group consisting of plastic, glass, paper, paperboard and a laminated combination thereof.

60. The component according to claim 57, wherein the material of the lowermost conductive layer is selected from a group consisting of transparent semiconducting oxide, non-transparent semiconducting oxide, metal, conductive ink, conductive polymer, and a combination thereof.

61. The component according to claim 57, wherein the distance between the electrode patterns in the direction perpendicular to the plane of the substrate is in the range of 1 to 50 μm.

62. The component according to claim 57, wherein the component comprises at least one upper active layer formed on top of said electrode pattern, the material of said layer being an organic or inorganic semiconducting material.

63. The component according to claim 62, wherein said at least one upper active layer is arranged to form a structure selected from the group of a channel structure of a transistor, a photoactive layer of a solar cell, a photocell, and an electroluminescent layer of a light-emitting component.

64. The component according to claim 57, wherein the component is selected from the group of a light emitting diode, a field effect transistor, an active or passive pixel display, a photocell, and a solar cell.

65. The component according to claim 57, wherein the component comprises one or more upper layers, whose perpendicular dimension with respect to the plane of the substrate is determined by the embossing operation exerted on the lowermost conductive layer.

66. The component according to claim 65, wherein the component is an organic field effect transistor OFET, the length of whose channel structure is determined by embossing in the direction perpendicular to the plane of the substrate.

67. The component according to claim 57, wherein the component is a pixel display based on organic light emitting diodes OLED, in which individual pixels of the display are formed in the intersections of crossing stripe-like electrodes representing different polarities, and in which component parallel adjacent electrodes representing the same polarity are formed on different levels with respect to the substrate in the direction perpendicular to the plane of the substrate.

68. The component according to claim 57, wherein the distance between said parallel adjacent electrodes representing the same polarity is in the range 1 to 5 μm, said distance being in the direction perpendicular to the plane of the substrate.
